(19) United States
(12) Patent Application Publication
(10) Pub. No.: US 2026/0047356 A1
(43) Pub. Date: Feb. 12, 2026

(54) METHODS OF FORMING TRANSITION METAL DICHALCOGENIDE FILMS

(71) Applicants: Applied Materials, Inc., Santa Clara, CA (US); National University of Singapore, Singapore (SG)

(72) Inventors: Chandan Das, Singapore (SG); Muhammed Juvaid Mangattuchali, Singapore (SG); Jiecong Tang, Singapore (SG); John Sudijono, Singapore (SG); Silvija Gradecak-Garaj, Singapore (SG)

(73) Assignees: Applied Materials, Inc., Santa Clara, CA (US); National University of Singapore, Singapore (SG)

(21) Appl. No.: 18/797,846

(22) Filed: Aug. 8, 2024

(51) Int. Cl. H01L 21/02; C23C 16/02; C23C 16/40; C23C 16/56; H01L 21/26; H01L 21/324

(52) U.S. Cl. CPC H01L 21/02568; C23C 16/02; C23C 16/405; C23C 16/56; H01L 21/02614; H01L 21/02658; H01L 21/26; H01L 21/324

(57) ABSTRACT

Methods of depositing transition metal dichalcogenide (TMDC) films are described. The TMDC films can be used in electronic devices as, for example, a channel material in both back-end-of-line (BEOL) and front-end-of line (FEOL) applications depending on the TMDC growth temperature.

### TECHNICAL FIELD

Embodiments of the disclosure generally relate to methods of forming transition metal dichalcogenide (TMDC) films. More particularly, embodiments of the disclosure are directed to methods of forming TMDC films for channel material applications in both front-end-of line (FEOL) and back-end-of-line (BEOL) processes.

### BACKGROUND

The advancing complexity of advanced microelectronic devices is placing stringent demands on currently used deposition techniques. Unfortunately, there is a limited number of viable chemical precursors and processes to provide films with suitable crystallinity, grain size, thickness, uniformity, conformality, and electrical conductivity. Additionally, achieving higher transistor density, speed, and lower power remains a challenge in conventional silicon-based films at lower technology nodes, such as <7 nm.

Transition metal dichalcogenides (TMDCs) are thought to be a promising channel material in ultra-thin limit (<2 nm) to overcome the short channel effects associated with the downscaling of the channel. It is thought that TMDCs'unique layered structure and dangling bond-free nature make them a promising choice for ultra-thin channel materials in both FEOL and BEOL processes. Moreover, it has been found that the carrier mobility of TMDC films has little dependence on thickness and higher carrier mobility values, especially at a lower channel thickness, such as <2 nm.

For two-dimensional (2D) channel material applications, for example, existing 2D channel material growth techniques typically rely on chemical vapor deposition (CVD) or metal organic chemical vapor deposition (MOCVD), where precise thickness control, wafer-scale uniformity, and conformality are challenges. In some cases, a seeding promoter has been used. Moreover, the growth time for a single layer of TMDC film by conventional CVD is a few hours.

Accordingly, there is a need for improved processes for depositing TMDC films for channel material applications.

### SUMMARY

One or more embodiments of the disclosure are directed to a method of forming a transition metal dichalcogenide (TMDC) film. The method comprises depositing a transition metal oxide film on a substrate by sequentially exposing the substrate to a transition metal precursor and an oxidant without forming a transition metal film intermediate; converting the transition metal oxide film to the TMDC film; and performing a rapid thermal anneal (RTA) process.

Additional embodiments of the disclosure are directed to a method of forming a transition metal dichalcogenide (TMDC) film. The method comprises depositing the TMDC film on a substrate by sequentially exposing the substrate to a transition metal precursor and a chalcogenide precursor at a temperature in a range of from 20° C. to 450° C.; exposing the TMDC film to the chalcogenide precursor at a temperature in a range of from 300° C. to 1000° C. and a pressure in a range of from 1 mTorr to 760 Torr; and performing a rapid thermal anneal (RTA) process.

Further embodiments of the disclosure are directed to a method of forming a transition metal dichalcogenide (TMDC) film. The method comprises: depositing an amorphous transition metal dichalcogenide (TMDC) film on a substrate by sequentially exposing the substrate to a transition metal precursor and a chalcogenide precursor at a temperature in a range of from 20° C. to 270° C.; performing a plasma post-treatment process; and performing a rapid thermal anneal (RTA) process.

### BRIEF DESCRIPTION OF THE DRAWINGS

So that the manner in which the above recited features of the disclosure can be understood in detail, a more particular description of the disclosure, briefly summarized above, may be had by reference to embodiments, some of which are illustrated in the appended drawings. It is to be noted, however, that the appended drawings illustrate only typical embodiments of the disclosure and are therefore not to be considered limiting of its scope, for the disclosure may admit to other equally effective embodiments. The embodiments as described herein are illustrated by way of example and not limitation in the Figures, in which like references indicate similar elements.

FIG. 1 illustrates a process flow diagram of a method in accordance with one or more embodiments of the disclosure;

FIG. 2A illustrates a cross-sectional view of a substrate in accordance with one or more embodiments of the disclosure;

FIG. 2B illustrates a cross-sectional view of a substrate in accordance with one or more embodiments of the disclosure;

FIG. 3A illustrates a cross-sectional view of a substrate in accordance with one or more embodiments of the disclosure;

FIG. 3B illustrates a cross-sectional view of a substrate in accordance with one or more embodiments of the disclosure;

FIG. 3C illustrates a cross-sectional view of a substrate in accordance with one or more embodiments of the disclosure; and

FIG. 4 illustrates a schematic representation of a processing system in accordance with one or more embodiments of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

The term “about” as used herein means approximately or nearly and in the context of a numerical value or range set forth means a variation of ±15% or less, of the numerical value. For example, a value differing by ±14%, ±10%, ±5%, ±2%, ±1%, ±0.5%, or ±0.1% would satisfy the definition of about.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” may encompass both an orientation of above and below. The device may be otherwise oriented (rotated 90 degrees or at other orientations) and the spatially relative descriptors used herein interpreted accordingly.

The use of the terms “a” and “an” and “the” and similar referents in the context of describing the materials and methods discussed herein (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein.

All methods described herein can be performed in any suitable order unless otherwise indicated herein or otherwise clearly contradicted by context. The use of any and all examples, or exemplary language (e.g., “such as”) provided herein, is intended merely to better illuminate the materials and methods and does not pose a limitation on the scope unless otherwise claimed. No language in the specification should be construed as indicating any non-claimed element as essential to the practice of the disclosed materials and methods.

Reference throughout this specification to “one embodiment,” “some embodiments,” “certain embodiments,” “one or more embodiment” or “an embodiment” means that a particular feature, structure, material, or characteristic described in connection with the embodiment is included in at least one embodiment of the disclosure. Thus, the appearances of the phrases such as “in some embodiments,” “in one or more embodiment,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

As used in this specification and the appended claims, the term “substrate” refers to a surface, or portion of a surface, upon which a process acts. It will also be understood by those skilled in the art that reference to a substrate can also refer to only a portion of the substrate unless the context clearly indicates otherwise. Additionally, reference to depositing on a substrate can mean both a bare substrate and a substrate with one or more films or features deposited or formed thereon.

A “substrate” may include materials such as silicon (including doped or undoped silicon), silicon oxide, strained silicon, silicon on insulator (SOI), carbon doped silicon oxides, amorphous silicon, germanium, gallium arsenide, glass, sapphire, and any other materials such as metals, metal nitrides, metal alloys, and other conductive materials, depending on the application. Substrates include, without limitation, semiconductor substrates. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

The substrate may have one or more features formed therein, one or more layers formed thereon, or combinations thereof. The shape of the feature can be any suitable shape including, but not limited to, trenches, holes and vias (circular or polygonal). As used in this regard, the term “feature” refers to any intentional surface irregularity. Suitable examples of features include but are not limited to trenches, which have a top, two sidewalls comprising, for example, a dielectric material, and a bottom extending into the substrate, the bottom comprising, for example, a metallic material, or vias which have one or more sidewall extending into the substrate to a bottom, and slot vias.

The features described herein can extend vertically into the substrate and/or laterally within the substrate. Unless specifically indicated otherwise, the features described herein are not limited to either of a vertically extending feature or a laterally extending feature. In one or more embodiments, the substrate comprises at least one vertically extending feature. In one or more embodiments, the substrate comprises at least one laterally extending feature. In one or more embodiments, the substrate comprises at least one vertically extending feature and at least one laterally extending feature.

The features described herein can have any suitable aspect ratio (ratio of the depth of the feature to the width of the feature). In one or more embodiments, the aspect ratio of the features described herein is greater than or equal to about 1:1, 2:1, 5:1, 10:1, 15:1, 20:1, 25:1, 30:1, 35:1, 40:1, 50:1, 60:1, 70:1, 80:1, 90:1, 100:1, 125:1, or 150:1. In one or more embodiments, the aspect ratio of the features described herein is in a range of from 1:1 to 150:1.

The term “on” indicates that there is direct contact between elements. The term “directly on” indicates that there is direct contact between elements with no intervening elements.

As used herein, the term “in situ” refers to processes that are all performed in the same processing chamber or within different processing chambers that are connected as part of an integrated processing system, such that each of the processes are performed without an intervening vacuum break. As used herein, the term “ex situ” refers to processes that are performed in at least two different processing chambers such that one or more of the processes are performed with an intervening vacuum break. In some embodiments, processes are performed without breaking vacuum or without exposure to ambient air.

As used in this specification and the appended claims, the terms “precursor”, “reactant”, “reactive gas” and the like are used interchangeably to refer to any gaseous species that can react with the substrate surface.

As used herein, “chemical vapor deposition” refers to a process in which a substrate surface is exposed to precursors and/or reactants simultaneously or substantially simultaneously. As used herein, “substantially simultaneously” refers to either co-flow or where there is overlap for a majority of exposures of the precursors and/or reactants. Plasma-enhanced chemical vapor deposition (PECVD) methods add a plasma exposure to traditional CVD methods. In some PECVD methods, an inert gas source is provided as the plasma. Embodiments described herein in reference to a PECVD process can be carried out using any suitable deposition system.

“Atomic layer deposition” or “cyclical deposition” as used herein refers to the sequential exposure of two or more reactive species to deposit a layer of material on a substrate surface. The substrate, or portion of the substrate, is exposed separately to the two or more reactive species which are introduced into a reaction zone of a processing chamber. In a time-domain ALD process, exposure to each reactive species is separated by a time delay to allow each compound to adhere and/or react on the substrate surface and then be purged from the processing chamber. These reactive species are said to be exposed to the substrate sequentially.

As used herein, the terms “purge” or “purging” each independently include any suitable purge process that removes unreacted precursor/reactant, reaction products, and by-products from the process region (e.g., a processing chamber). The suitable purge process includes moving the substrate through a gas curtain to a portion or sector of the processing region that contains none or substantially none of the precursor/reactant. In one or more embodiments, purging the processing chamber comprises applying a vacuum. In some embodiments, purging the processing region comprises flowing a purge gas over the substrate. In some embodiments, the purge process comprises flowing an inert gas. In one or more embodiments, the purge gas is selected from one or more of nitrogen (N₂), helium (He), and argon (Ar). In some embodiments, the first reactive species is purged from the processing chamber for a time duration in a range of from 0.1 seconds to 30 seconds, from 0.1 seconds to 10 seconds, from 0.1 seconds to 5 seconds, from 0.5 seconds to 30 seconds, from 0.5 seconds to 10 seconds, from 0.5 seconds to 5 seconds, from 1 seconds to 30 seconds, from 1 seconds to 10 seconds, from 1 seconds to 5 seconds, from 5 seconds to 30 seconds, from 5 seconds to 10 seconds or from 10 seconds to 30 seconds before exposing the substrate to the second reactive species.

In a spatial ALD process, different portions of the substrate surface, or material on the substrate surface, are exposed simultaneously to the two or more reactive species so that any given point on the substrate is substantially not exposed to more than one reactive species simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas is introduced into the processing chamber to purge the reaction zone or otherwise remove any residual reactive species or reaction by-products from the reaction zone. Alternatively, the purge gas may flow continuously throughout the deposition process so that only the purge gas flows during the time delay between pulses of reactive species. The reactive species are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas.

As used herein, the terms “thermal” or “thermal process(es)” refer to a type of reactant or deposition technique, respectively, that does not involve the use of plasma. As used herein, the term “plasma” refers to a composition have ionically charged species and uncharged neutral and radical species. As used herein, a “radical-rich plasma” comprises greater than 50 % radical species.

Plasma-enhanced atomic layer deposition (PEALD) methods add a plasma exposure to traditional ALD methods. In some PEALD methods, an inert gas source is provided as the plasma. The primary benefit of PEALD methods is the relatively low substrate temperature, e.g., less than or equal to 600° C., during processing. Embodiments described herein in reference to a PEALD process can be carried out using any suitable deposition system.

As used herein, as will be understood by the skilled artisan, a layer/film which is “conformal” or “conformally deposited” refers to a layer/film where the thickness is about the same throughout. A layer/film which is conformal varies in thickness by less than or equal to about 5 %, 2 %, 1 % or 0.5 %.

Transistors are circuit components or elements that are often formed on semiconductor devices. Depending upon the circuit design, in addition to capacitors, inductors, resistors, diodes, conductive lines, or other elements, transistors are formed on a semiconductor device. Generally, a transistor includes a gate formed between source and drain regions. In one or more embodiments, the source and drain regions include a doped region of a substrate, such as a semiconductor substrate, and exhibit a doping profile suitable for a particular application. The gate is positioned over the channel region and includes a gate dielectric interposed between a gate electrode and the channel region in the semiconductor substrate.

As used herein, the term “field effect transistor” or “FET” refers to a transistor that uses an electric field to control the electrical behavior of the device. Field effect transistors are voltage controlled devices where their current carrying ability is changed by applying an electric field. Field effect transistors generally display very high input impedance at low temperatures. The conductivity between the drain and source terminals is controlled by an electric field in the device, which is generated by a voltage difference between the body and the gate of the device. The FET's three terminals are source (S), through which the carriers enter the channel; drain (D), through which the carriers leave the channel; and gate (G), the terminal that modulates the channel conductivity. Conventionally, current entering the channel at the source (S) is designated I_{S} and current entering the channel at the drain (D) is designated I_{D}. Drain-to-source voltage is designated V_{DS}. By applying voltage to gate (G), the current entering the channel at the drain (i.e. I_{D}) can be controlled.

The metal-oxide-semiconductor field-effect transistor (MOSFET) is a type of field-effect transistor (FET) and is used in integrated circuits and high speed switching applications. MOSFET has an insulated gate, whose voltage determines the conductivity of the device. This ability to change conductivity with the amount of applied voltage is used for amplifying or switching electronic signals. A MOSFET is based on the modulation of charge concentration by a metal-oxide-semiconductor (MOS) capacitance between a body electrode and a gate electrode located above the body and insulated from all other device regions by a gate dielectric layer. Compared to the MOS capacitor, the MOSFET includes two additional terminals (source and drain), each connected to individual highly doped regions that are separated by the body region. These regions can be either p or n type, but they are both of the same type, and of opposite type to the body region. The source and drain (unlike the body) are highly doped as signified by a “+” sign after the type of doping.

Generally, a metal oxide semiconductor (MOS) transistor is a structure obtained by growing a high-κ dielectric layer on a layer of silicon dioxide (SiO₂) on top of a silicon substrate, followed by depositing a layer of metal or polycrystalline silicon on the high-κ dielectric layer. A CMOS device is a MOS transistor consisting of paired p-channel transistors and n-channel transistors.

If the MOSFET is an n-channel or NMOS FET (‘NMOS” or “NFET”), then the source and drain are n+ regions and the body is a p region. If the MOSFET is a p-channel or PMOS FET (“PMOS” or “PFET”), then the source and drain are p+ regions and the body is an n region. The source is so named because it is the source of the charge carriers (electrons for n-channel, holes for p-channel) that flow through the channel; similarly, the drain is where the charge carriers leave the channel. A silicon germanium (SiGe) channel is one attractive feature for a gate-all-around (GAA) (nanowire or nanosheet) to achieve a high mobility “PMOS” or “PFET”.

An “NMOS” or “NFET” is a MOS transistor where the active carriers are electrons flowing between n-type source and drain regions in an electrostatically formed n-channel in a p-type silicon substrate. A “PMOS” or “PFET” is a P-channel MOS transistor where the active carriers are holes flowing between p-type source and drain regions in an electrostatically formed p-channel in an n-type silicon substrate.

Generally, a “PMOS” or “PFET” comprises a silicon germanium (SiGe) channel between a source and drain region and the “NMOS” or “NFET” comprises a silicon (Si) channel between a source region and a drain region.

As used herein, the term “fin field-effect transistor (FinFET)” refers to a MOSFET transistor built on a substrate where the gate is placed on two, three, or four sides of the channel or wrapped around the channel, forming a double gate structure. FinFET devices have been given the generic name FinFETs because the source/drain region forms “fins” on the substrate. FinFET devices have fast switching times and high current density.

As used herein, the term “gate-all-around (GAA),” is used to refer to an electronic device, e.g., a transistor, in which the gate material surrounds the channel region on all sides. The channel region of a GAA transistor may include nanowires, nanosheets, nanoslabs, bar-shaped channels, or other suitable channel configurations known to one of skill in the art. In one or more embodiments, the channel region of a GAA device has multiple horizontal nanowires or horizontal bars vertically spaced, making the GAA transistor a stacked horizontal gate-all-around (hGAA) transistor.

As used herein, the term “nanowire” refers to a nanostructure, with a diameter on the order of a nanometer (10⁻⁹ meters). Nanowires can also be defined as the ratio of the length to width being greater than 1000. Alternatively, nanowires can be defined as structures having a thickness or diameter constrained to tens of nanometers or less and an unconstrained length. Nanowires are used in transistors and some laser applications, and, in one or more embodiments, are made of semiconducting materials, metallic materials, insulating materials, superconducting materials, or molecular materials. In one or more embodiments, nanowires are used in transistors for logic CPU, GPU, MPU, and volatile (e.g., DRAM) and non-volatile (e.g., NAND) devices. As used herein, the term “nanosheet” refers to a two-dimensional nanostructure with a thickness in a scale ranging from about 0.1 nm to about 1000 nm, or from 0.5 nm to 500 nm, or from 0.5 nm to 100 nm, or from 1 nm to 500 nm, or from 1 nm to 100 nm, or from 1 nm to 50 nm.

Embodiments of the disclosure advantageously provide methods of forming high-quality TMDC films in terms of precise thickness control, wafer-scale uniformity, crystallinity, grain size, smoothness, conformality, and/or electrical conductivity. Some embodiments advantageously provide methods of forming high-quality 2D-TMDC films for temperature-sensitive device architectures. Some embodiments advantageously provide methods of forming high-quality TMDC films directly on a substrate without the need for additional film transferring. Some embodiments advantageously provide methods of forming high-quality TMDC films with a reduced amount of precursor/reactant consumption relative to current 2D channel growth techniques, e.g., conventional chemical vapor deposition (CVD).

Embodiments of the disclosure advantageously provide methods of forming TMDC films via a low energy pathway. In some embodiments, in the low energy pathway, the transition metal precursors are used in their various forms (metal, metal oxide, metal chloride, metal oxychloride, and the like). In one or more embodiments, the methods include depositing an ultrathin layer, followed by oxidation, then exposure to a chalcogenide precursor, (e.g., sulfurization), which forms high-quality TMDC films. Advantageously, the methods described herein provide a low energy pathway for sulfurization of transition metals or their precursors to metal sulfides. Based on this low energy pathway, the methods described herein advantageously form a conformal and uniform TMDC film.

One or more embodiments advantageously provide methods of depositing TMDC films in high aspect ratio structures, e.g., in memory devices or logic devices, including, but not limited to, 3D-NAND, dynamic random-access memory (DRAM) cells, 3D DRAM, Fin field effect transistors (FinFET), gate-all-around (GAA) transistors, nanosheet devices, and the like. As used herein, a “high aspect ratio” structure has an aspect ratio greater than or equal to about 20:1, such as, for example, in a range of from 50:1 to 150:1. In some embodiments, the TMDC film is conformally deposited on the high aspect ratio feature, such as at least one vertically extending feature and/or at least one laterally extending feature.

Some embodiments provide methods of forming TMDC films by thermal or plasma-based processes.

Advantageously, the TMDC films can be used for channel material applications in both FEOL and BEOL processes in the miniaturization and scaling of integrated circuits. In one or more embodiments, the TMDC films deposited at less than or equal to 450° C. are used for BEOL applications.

It has been found that silicon (Si) MOSFET at <7 nm faces challenges due to physical limitations. Additionally, achieving higher transistor density, speed, and lower power remains a challenge in conventional silicon-based films at lower technology nodes, such as <7 nm. In particular, it has been found that the carrier mobility of silicon (Si) decreases with decreasing thickness in sub 5 nm technology nodes.

Two-dimensional (2D) semiconductors, such as the TMDC films according to one or more embodiments, can be advantageously used to overcome the short-channel effects in MOSFET by providing a unique layered structure and dangling-bond-free surface. Advantageously, it has been found that the carrier mobility of TMDC films has little dependence on thickness and higher carrier mobility values, especially at a lower channel thickness, such as <2 nm. The TMDC films according to one or more embodiments advantageously have greater mechanical strength, e.g., a greater biaxial Young's Modulus, than silicon (Si). Therefore, the TMDC films according to one or more embodiments can advantageously be used instead of silicon (Si) or silicon germanium (SiGe), for example, as a channel material in future device architectures, including nanosheet devices.

The embodiments of the disclosure are described by way of the Figures, which illustrate processes and substrates in accordance with one or more embodiments of the disclosure. The processes, schemes, and resulting substrates shown are merely illustrative of the disclosed processes, and the skilled artisan will recognize that the disclosed processes are not limited to the illustrated applications.

In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

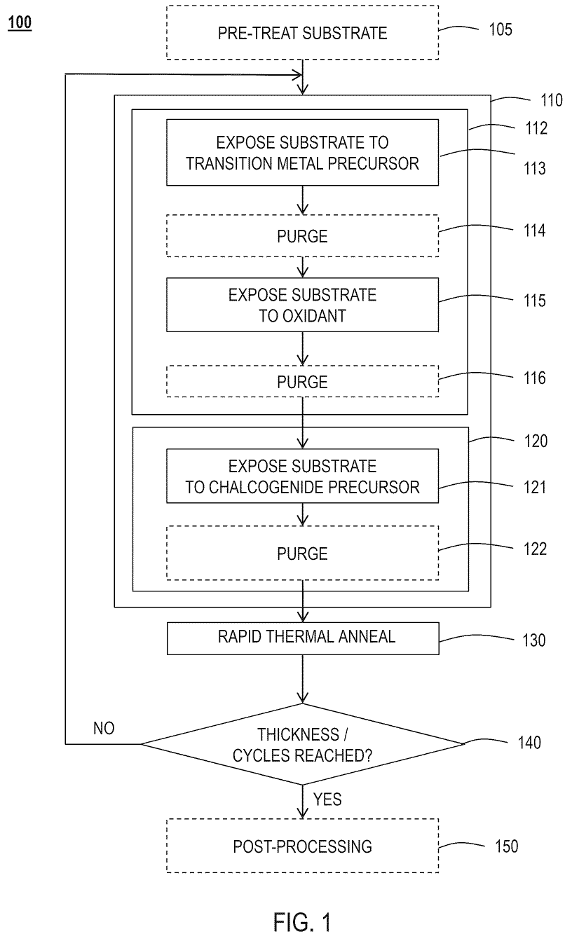

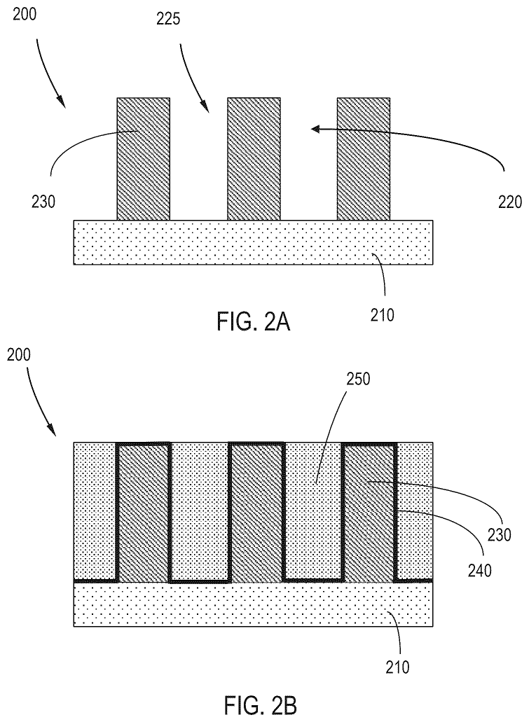

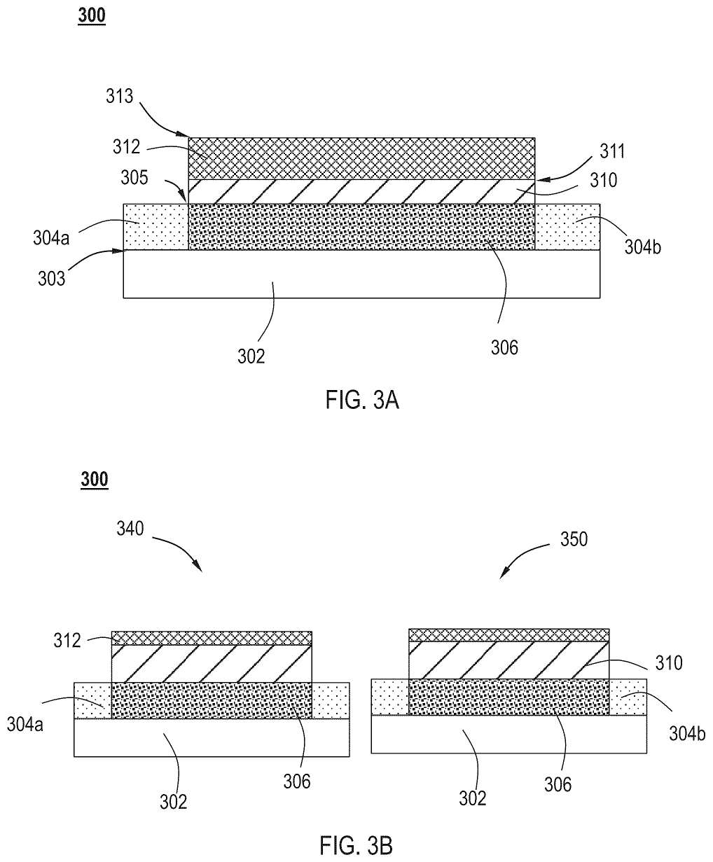

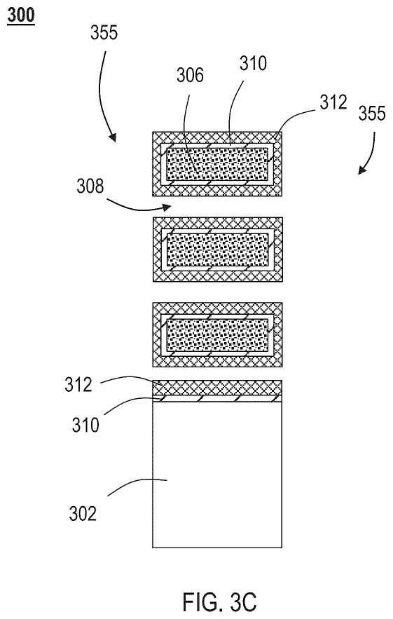

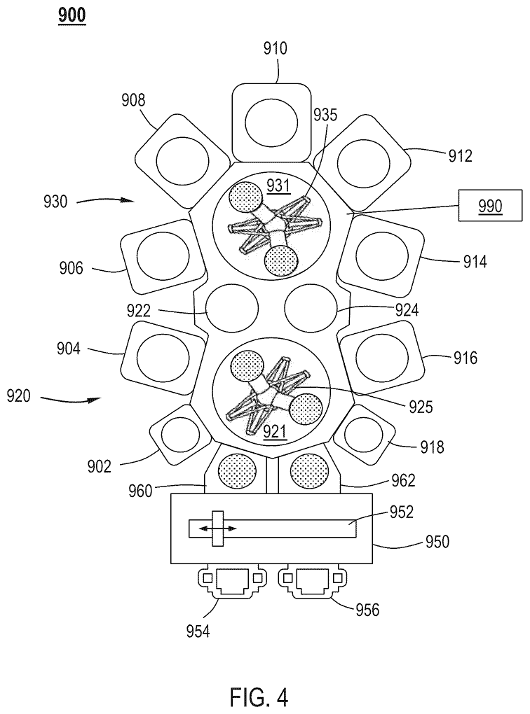

FIG. 1 illustrates a process flow diagram of a method 100 of forming a TMDC film. FIGS. 2A and 2B illustrate cross-sectional views of a substrate 200 in accordance with one or more embodiments of the disclosure. FIG. 3A-3C illustrate an electronic device 300, and particularly, cross-sectional views of a substrate 302 that is part of the electronic device 300. The method 100 can be used to form a TDMC film on a substrate, such as, for example, the substrate 200 shown in FIGS. 2A, 2B, and the r substrate 302 shown in 3A-3C. FIG. 4 illustrates a schematic representation of a processing system 900 for processing the substrates 200, 302, forming the electronic devices shown (e.g., electronic device 300) and/or performing the methods described herein.

The operations of method 100 can be performed in any suitable order. In one or more embodiments, the method 100 is an atomic layer deposition (ALD) process in which the substrate is exposed sequentially to the reactive gases in a manner that prevents or minimizes gas phase reactions of the reactive gases.

In one or more embodiments, the method 100 comprises optionally pre-treating the substrate at operation 105.

A TMDC film is formed on the substrate in a deposition process cycle 110. The deposition process cycle 110 can be understood in two phases: a first phase 112 and a second phase 120.

The first phase 112 comprising operations 113, 114, 115, 116, forms a transition metal oxide film on the substrate. In the first phase 112, the transition metal oxide film is directly formed without forming a transition metal film intermediate.

The second phase 120 comprising operations 121 and 122 converts the transition metal oxide film formed in the first phase 112 to a TMDC film.

At operation 130, the method 100 comprises performing a rapid thermal anneal (RTA) process. Advantageously, the RTA process of operation 130 improves the quality of the TMDC film.

In one or more embodiments, the method 100 includes pre-treating the substrate at operation 105 prior to depositing the transition metal oxide film (e.g., prior to the first phase 112). The pre-treatment can be any suitable pre-treatment process known to the skilled artisan. Suitable pre-treatments include, but are not limited to, pre-heating, cleaning, soaking, native oxide removal, or the like.

In some embodiments, the method 100 comprises pre-treating the substrate at operation 105 depending on the substrate used. In some embodiments, the method 100 comprises pre-treating the substrate, such as a substrate comprising a low-κ dielectric material, e.g., silicon oxycarbide (SiOC), at operation 105. In some embodiments, the method 100 comprises pre-treating the substrate at operation 105 with a plasma pre-treatment or ultraviolet (UV) radiation exposure to remove surface alkyl groups and make the low-κ dielectric surface, for example, suitable for precursor adsorption. In one or more embodiments, the method 100 does not include pre-treating the substrate at operation 105.

In one or more embodiments, the plasma treatment of operation 105 comprises exposing the substrate surface to a plasma of carbon dioxide (CO₂). In one or more embodiments, the plasma of CO₂ further comprises an inert gas, including, but not limited to, argon (Ar), helium (He), or nitrogen (N₂). In one or more embodiments, the substrate surface is exposed to the plasma of CO₂ for a time period in a range of from about 0.5 seconds to about 20 seconds.

In specific embodiments, it has advantageously been found that exposing the substrate surface to the plasma of CO₂ for a time period in a range of from about 0.5 seconds to about 20 seconds does not modify the properties of, or damage, the substrate, such as a low-κ dielectric surface, where there is no change in κ-value.

In one or more embodiments, the pre-treatment of operation 105 comprises exposing the substrate to ultraviolet (UV) radiation. In one or more embodiments, the pre-treatment of operation 105 comprises exposing the substrate to UV radiation for a time period in a range of from about 0.5 seconds to about 30 seconds. In one or more embodiments, exposing the substrate to UV radiation includes using a UV lamp that generates the UV radiation.

The first phase 112 comprises sequentially exposing the substrate to a transition metal precursor at operation 113, optionally purging the substrate at operation 114, exposing the substrate to an oxidant at operation 115, and optionally purging the substrate at operation 116 to deposit the transition metal oxide film.

The first phase 112 can be performed at any suitable processing conditions depending on the transition metal precursor and/or oxidant used. In one or more embodiments, depositing the transition metal oxide film (the first phase 112) is performed at a pressure in a range of from 1 mTorr to 10 Torr. In one or more embodiments, depositing the transition metal oxide film (the first phase 112) is performed at a temperature in a range of from 20° C. to 450° C.

In the first phase 112 of the deposition process cycle 110, in one or more embodiments, at operation 113, the substrate is exposed to a transition metal precursor to form a reactive metal species on the substrate. The transition metal precursor can be any suitable transition metal containing compound that can react (i.e., adsorb or chemisorb onto) the substrate to leave a transition metal containing species on the substrate. It is thought that any transition metal containing compound, which, based on its size, can inhibit diffusion through pores in the substrate surface, where each pore has a size in a range of from 5 Å to 20 Å, is suitable.

The transition metal precursor can be any precursor comprising one or more of molybdenum (Mo), tungsten (W), tantalum (Ta), titanium (Ti), niobium (Nb), zirconium (Zr), hafnium (Hf), rhenium (Re), platinum (Pt), palladium (Pd), or nickel (Ni). In one or more embodiments, the transition metal precursor is selected from the group consisting of molybdenum (Mo), tungsten (W), tantalum (Ta), titanium (Ti), niobium (Nb), zirconium (Zr), hafnium (Hf), rhenium (Re), platinum (Pt), palladium (Pd), and nickel (Ni).

In one or more embodiments, the transition metal precursor comprises, consists essentially of, or consists of one or more of bis(t-butylimino) bis(dimethylamino) tungsten(VI), bis(isopropylcyclopentadienyl) tungsten(IV) dihydride, bis(cyclopentadienyl) tungsten dihydride, bis(t-butylimino) bis(dimethylamino) molybdenum(VI), pentakis (dimethylamino) tantalum (V), or tetrakis (dimethylamido) titanium (IV).

At operation 114, the processing chamber or substrate is optionally purged to remove unreacted transition metal precursor, reaction products, and byproducts.

At operation 115, the is exposed to an oxidant to form a transition metal oxide film on the substrate. The oxidant (which may also be referred to as an oxide reactant) may be any suitable compound for oxidizing the adsorbed transition metal precursor to form a transition metal oxide film. In some embodiments, pre-treating the substrate surface at operation 105 comprises a plasma treatment or ultraviolet (UV) radiation exposure to remove surface alkyl groups and make the low-κ dielectric surface suitable for precursor adsorption.

In one or more embodiments, the oxidant comprises, consists essentially of, or consists of one or more of thermal oxygen (O₂), a plasma of oxygen (O₂), thermal ozone (O₃), a plasma of ozone (O₃), an alcohol, or deionized water.

The alcohol can be any suitable alcohol. In one or more embodiments, the alcohol used for the oxidant comprises one or more of methanol, ethanol or isopropyl alcohol. In one or more embodiments, the alcohol used for the oxidant comprises isopropyl alcohol.

As used herein, “deionized water” includes any water composition in which dissolved oxygen (DO) has been removed. In embodiments where the oxidant comprises deionized water, DO can be removed by any suitable process known to the skilled artisan, and it is to be understood that the disclosure is not limited to any specific process.

At operation 116, the processing chamber or substrate is optionally purged to remove unreacted oxidant, reaction products, and byproducts.

In one or more embodiments, the first phase 112 includes exposing the substrate to the transition metal precursor (operation 113), the purge gas (operation 114), the oxidant (operation 115), and the purge gas (operation 116). The transition metal precursor and the oxidant react to form a product compound as the transition metal oxide film on the substrate. The first phase 112 may be repeated to form the transition metal oxide film to a desired thickness.

In one or more embodiments, the transition metal oxide film is formed with precise thickness control. In one or more embodiments, the transition metal oxide film is formed to a thickness in a range of 5 Å to 100 Å, such as in a range of 5 Å to 50 Å, in a range of 5 Å to 35 Å, in a range of 5 Å to 25 Å, or in a range of 5 Å to 10 Å. In one or more embodiments, the transition metal oxide film is formed as a monolayer. In one or more embodiments, the transition metal oxide film comprises a plurality of monolayers, such as, for example, in a range of from 2 monolayers to 10 monolayers. The first phase 112 may be repeated until the transition metal oxide film is formed to the desired thickness.

It has been advantageously found that purging the processing chamber at operation 116 enhances the adsorption of the transition metal precursor if returning to the beginning of the first phase 112 to deposit additional transition metal oxide film. Without being bound by theory, it is believed that the purge at operation 116 provides a “clean” substrate, which enhances the adsorption of the transition metal precursor in operation 113.

In some embodiments, the transition metal oxide film formed in the first phase 112 is directly formed without forming a transition metal film intermediate. It has been found that the formation of certain metals (e.g., tungsten) on dielectric surfaces is more difficult (e.g., longer processing times, elevated temperatures) than the formation of metal oxides. Further, the formation of a metal layer which is subsequently oxidized requires more processing time and decreases processing throughput. Accordingly, embodiments of the disclosure advantageously provide methods of forming a transition metal oxide film in the first phase 112 without the formation of a metal film intermediate.

The transition metal oxide film formed in the first phase 112 can be amorphous or polycrystalline depending on the processing conditions used. In one or more embodiments, transition metal oxide films grown at a temperature less than or equal to 270° C. were amorphous in nature. In one or more embodiments, transition metal oxide films grown at a temperature greater than 270° C. were polycrystalline in nature.

Typically, an amorphous transition metal oxide film converts to an amorphous transition metal dichalcogenide (TMDC) at temperatures less than or equal to 270° C. and relatively lower pressure such as, for example, in a range of from 100 mTorr to 1 Torr. However, without intending to be bound by any particular theory, it is thought that temperatures greater than 270° C. lead to crystalline TMDC films irrespective of the transition metal oxide film's crystallinity. The grain size of the TMDC film may be dependent on the crystallinity of transition metal oxide film. Without intending to be bound by any particular theory, it is thought that an amorphous transition metal oxide film with no grain boundaries may eventually lead to larger grains in the TMDC film.

Once the first phase 112 is completed, and the transition metal oxide film has reached a predetermined thickness or a predetermined number of process cycles have been performed, the method 100 moves to the second phase 120.

The second phase 120 comprises sequentially exposing the substrate to a chalcogenide precursor at operation 121 and, optionally, purging the substrate at operation 122 to convert the transition metal oxide film to the TMDC film.

Without intending to be bound by any particular theory, it is thought that converting an amorphous transition metal oxide film may more easily achieve larger crystalline grains, whereas polycrystalline transition metal oxide films may be limited by their initial small grains.

In some embodiments, the second phase 120 is performed after the first phase 112 has deposited the transition metal oxide film to a predetermined thickness. In some embodiments, the second phase 120 is performed after a single cycle of the first phase 112. In some embodiments, the second phase 120 is performed after multiple cycles of the first phase 112.

In the second phase 120, the transition metal oxide film formed in the first phase 112 is converted to the TMDC film. In some embodiments, converting the transition metal oxide film comprises exposing the transition metal oxide film to a chalcogenide precursor at a temperature in a range of from 300° C. to 1000° C. (operation 121). The chalcogenide precursor comprises one of more of sulfur (S), selenium (Se), tellurium (Te), polonium (Po), or livermorium (Lv). In some embodiments, the chalcogenide precursor comprises one of more of sulfur (S), selenium (Se), tellurium (Te). In some embodiments, the chalcogenide precursor comprises one or more of hydrogen sulfide (H₂S), hydrogen selenide (H₂Se), or hydrogen telluride (H₂Te). In some embodiments, the chalcogenide precursor comprises hydrogen sulfide (H₂S). In some embodiments, the chalcogenide precursor further comprises an inert gas, including, but not limited to, argon (Ar), helium (He), or nitrogen (N₂). In some embodiments, the chalcogenide precursor is delivered without the inert gas. In some embodiments, the chalcogenide precursor further comprises hydrogen (H₂). In some embodiments, the chalcogenide precursor comprises a thermal reactant. In some embodiments, the chalcogenide precursor comprises a plasma.

In one or more embodiments, the transition metal oxide film is exposed to a chalcogenide precursor comprising thermal Ar/H₂S or H₂/H₂S gas. In one or more embodiments, the transition metal oxide film is exposed to a chalcogenide precursor comprising a plasma formed from Ar/H₂S or H₂/H₂S gas.

In one or more embodiments, where the transition metal oxide film is exposed to a chalcogenide precursor comprising a plasma, converting the transition metal oxide film to the TMDC film is conducted at a plasma power in a range of from 25 watts to 500 watts.

In some embodiments, converting the transition metal oxide film to the TMDC film is performed at a pressure in a range of from 1 mTorr to 760 Torr.

In one or more embodiments, converting the transition metal oxide film to the TMDC film is conducted for a time period in a range of from 1 minute to 60 minutes.

In one or more embodiments, the TMDC film has a general formula of MX₂, wherein M is a transition metal selected from the group consisting of molybdenum (Mo), tungsten (W), tantalum (Ta), titanium (Ti), niobium (Nb), zirconium (Zr), hafnium (Hf), rhenium (Re), platinum (Pt), palladium (Pd), and nickel (Ni) and X is a chalcogen selected from the group consisting of sulfur (S), selenium (Se), and tellurium (Te). In one or more embodiments, the TMDC film comprises molybdenum disulfide (MoS₂).

In one or more embodiments, the TMDC film is substantially free of oxygen. As used herein, “substantially free” means that there is less than or equal to about 5%, including less than or equal to about 4%, less than or equal to about 3%, less than or equal to about 2%, less than or equal to about 1%, or less than or equal to about 0.5% of oxygen, on an atomic basis, in the TMDC film. It is thought that the TMDC film that is formed without producing oxygen as a byproduct, thus advantageously minimizing the potential to etch/corrode underlying metal layers.

At operation 122, the processing chamber or substrate is optionally purged to remove unreacted chalcogenide precursor, reaction products, and byproducts.

At operation 130, the method 100 comprises annealing the TMDC film. Annealing the TMDC film comprises a first process or a second process.

The first process comprises exposing the transition metal dichalcogenide (TMDC) film to a chalcogenide precursor at a temperature in a range of from 400° C. to 1200° C. and a pressure in a range of from 1 mTorr to 760 Torr for a time period in a range of from 1 second to 60 minutes.

The second process comprises exposing the transition metal dichalcogenide (TMDC) film to an environment comprising one or more of nitrogen (N₂), argon (Ar), or hydrogen (H₂) under vacuum at a temperature in a range of from 400° C. to 1200° C. and a pressure in a range of from 0.01μTorr to 10 Torr for a time period in a range of from 1 second to 60 minutes, followed by exposing the TMDC film to a chalcogenide precursor at a temperature in a range of from 400° C. to 1200° C. and a pressure in a range of from 1 mTorr to 760 Torr for a time period in a range of from 1 second to 60 minutes.

It has been advantageously found that annealing the TMDC film at operation 130 improves the quality of the TMDC film. It has been advantageously found that annealing the TMDC film at operation 130 improves the continuity, smoothness, and/or crystallinity of the TMDC film, which in turn improves the electrical properties of the device in which the TMDC film is used.

In one or more embodiments, the method 100 comprises, consists essentially of, or consists of pre-treating the substrate (operation 105), deposition process cycle 110 including the first phase 112 [comprising sequentially exposing the substrate to a transition metal precursor at operation 113, purging the substrate at operation 114, exposing the substrate to an oxidant at operation 115, and purging the substrate at operation 116 to deposit the transition metal oxide film], and the second phase 120 [comprising sequentially exposing the substrate to a chalcogenide precursor at operation 121 and purging the substrate at operation 122 to convert the transition metal oxide film (formed in the first phase 112) to the TMDC film], and annealing the TMDC film in a first process or a second process at operation 130.

At decision 140, the method 100 includes determining whether the thickness of the TMDC film, and/or number of cycles of the deposition process cycles 110 has been reached. If the TMDC film has reached a predetermined thickness or a predetermined number of cycles have been performed, the method 100 moves to an optional post-processing operation 150. If the thickness of the TMDC film or the number of cycles has not reached the predetermined threshold, the method 100 returns to the beginning of the deposition process cycle 110 to form additional TMDC film.

In one or more embodiments, the TMDC film is formed as a monolayer. In one or more embodiments, the TMDC film comprises a plurality of monolayers, such as, for example, in a range of from 2 monolayers to 10 monolayers.

The optional post-processing operation 150 can be any suitable manufacturing process known to the skilled artisan such as, for example, a process to modify film properties (e.g., annealing) or a further film deposition process (e.g., additional ALD or CVD processes) to grow additional films.

Additional embodiments of the disclosure are directed to another aspect of the method 100. In some embodiments, the method 100 comprises depositing the TMDC film on a substrate by sequentially exposing the substrate to a transition metal precursor (operation 113) and a chalcogenide precursor (operation 121) at a temperature in a range of from 20° C. to 450° C.; exposing the TMDC film to the chalcogenide precursor (operation 121) at a temperature in a range of from 300° C. to 1000° C. and a pressure in a range of from 1 mTorr to 760 Torr; and performing a rapid thermal anneal (RTA) process (operation 130). In one or more embodiments, the method 100 comprises, consists essentially of, or consists of operation 113, operation 114, operation 121, operation 122, operation 121, operation 122, and operation 130.

Further embodiments of the disclosure are directed to another aspect of the method 100. In some embodiments, the method 100 comprises depositing an amorphous transition metal dichalcogenide (TMDC) film on a substrate by sequentially exposing the substrate to a transition metal precursor (operation 113) and a chalcogenide precursor (operation 121) at a temperature in a range of from 20° C. to 270° C.; performing a plasma post-treatment process (operation 150); and performing a rapid thermal anneal (RTA) process (operation 130). In one or more embodiments, the method comprises, consists essentially of, or consists of operation 113, operation 114, operation 121, operation 122, operation 150, and operation 130.

It has been advantageously found that the plasma post-treatment process (operation 150) described herein enhances grain size and crystallinity.

In one or more embodiments, the plasma post-treatment process (operation 150) comprises exposing the amorphous TMDC film to a plasma including one or more of argon (Ar), hydrogen (H₂), nitrogen (N₂), hydrogen sulfide (H₂S), hydrogen selenide (H₂Se), or hydrogen telluride (H₂Te). In one or more embodiments, the plasma post-treatment process (operation 150) is performed at a temperature in a range of from 20° C. to 500° C. and a pressure in a range of from 100 mTorr to 760 Torr. Advantageously, the plasma post-treatment process at operation 150 enhances grain size and crystallinity of the amorphous TMDC film, converting the amorphous TMDC film to a crystalline TMDC film.

Referring now to FIG. 2A, a substrate 200 including a base material 210 having at least one feature 220 formed from a material 230 is shown. The surfaces of the base material 210 and the material 230 form the substrate, i.e., substrate surface. In some embodiments, the base material 210 and the material 230 are the same. In some embodiments, the base material 210 is a metallic material or other conductive material. In some embodiments, the material 230 is a dielectric material.

The Figures show a substrate 200 having three features for illustrative purposes; however, those skilled in the art will understand that there can be more or fewer than three features. In one or more embodiments, the substrate 200 comprises at least one feature 220.

Referring now to FIG. 2B, each of the at least one feature 220 shown in FIG. 2A has a transition metal dichalcogenide (TMDC) film 240 deposited thereon. The TMDC film 240 is deposited on or directly on the at least one feature 220. In one or more embodiments, the TMDC film 240 is formed in accordance with the method 100 shown in FIG. 1. In one or more embodiments, the TMDC film 240 is conformally deposited directly on the at least one feature 220.

In FIGS. 2A and 2B, the substrate 200 having three features 220 has a gap 225 between each of the features 220. Gap fill processes are integral to several semiconductor manufacturing processes. A gap fill process can be used to fill a gap (or feature) with an insulating material or conducting material, as will be appreciated and understood by the skilled artisan.

In one or more embodiments, the substrate 200 includes a metal fill 250 that is deposited on the TMDC film 240 to fill the gap 225 between each of the features 220. In one or more embodiments, the metal fill 250 comprises a high-conductivity metal. In some embodiments, the metal fill 250 comprises one or more of copper (Cu), cobalt (Co), tungsten (W), molybdenum (Mo), or ruthenium (Ru).

In some embodiments, the metal fill 250 is substantially free of seams and/or voids. As used in this regard, “substantially free” means that less than about 5%, including less than about 4%, less than about 3%, less than about 2%, less than about 1%, less than about 0.5%, and less than about 0.1% of the total composition of the metal fill 250 on an atomic basis, comprises seams and/or voids. In embodiments where the substrate 200 includes the metal fill 250 deposited on the TMDC film 240 to fill the gap 225 between each of the features 220, the TMDC film 240 acts as a liner/barrier layer.

Referring to FIG. 3A-3C, the electronic device 300 includes an interfacial layer 310 on a top surface 305 of a channel 306 located between a source region 304a and a drain region 304b on the substrate 202. FIG. 3B illustrates an N-metal stack 340 (i.e., “NMOS”or “NFET”) and a P-metal stack 350 (i.e., “PMOS”or “PFET”).

The substrate 302 can be any suitable substrate material. In one or more embodiments, the substrate 302 comprises one or more of silicon (Si) or silicon germanium (SiGe).

In some embodiments, the source region 304a is on the top surface 303 of the substrate 302. In one or more embodiments, the source region 304a has a source and a source contact. A drain region 304b is on the top surface 303 of the substrate 302 opposite the source region 304a. In one or more embodiments, the drain region 304b has a drain and a drain contact.

In one or more embodiments, the source region 304a and/or the drain region 304b can be any suitable material known to the skilled artisan. In one or more embodiments, the source region 304a and/or the drain region 304b may have more than one layer. For example, the source region 304a and/or the drain region 304b may independently comprise three layers. In one or more embodiments, the source region 304a and the drain region 304b may independently comprise one or more of copper (Cu), cobalt (Co), tungsten (W), titanium (Ti), molybdenum (Mo), nickel (Ni), ruthenium (Ru), silver (Ag), gold (Au), iridium (Ir), platinum (Pt), phosphorus (P), germanium (Ge), silicon (Si), aluminum (Al), or zirconium (Zr). In some embodiments, the source region 304a and the drain region 304b may independently comprise a bottom layer of silicon with doped epi (e.g. SiGe, SiP, and the like), a second layer of silicide, which may contain nickel (Ni), titanium (Ti), aluminum (Al), and the like, and a third, or top, layer which may be a metal such as, but not limited to, cobalt, tungsten, ruthenium, and the like.

In some embodiments, the source region 304a and the drain region 304b may be raised source/drain regions formed by epitaxial growth. In one or more embodiments, the source contact and/or the drain contact may independently be selected from one or more of copper (Cu), cobalt (Co), tungsten (W), titanium (Ti), molybdenum (Mo), nickel (Ni), ruthenium (Ru), silver (Ag), gold (Au), iridium (Ir), tantalum (Ta), or platinum (Pt). In one or more embodiments, formation of the source contact and/or the drain contact is conducted by any suitable process known to the skilled artisan, including, but not limited to ALD, CVD, PVD, MBE, MOCVD, spin-on, or other insulating layer deposition techniques known to the skilled artisan.

In one or more embodiments, a channel 306 is located between the source region 304a and the drain region 304b. The channel 306 can comprise any suitable material. As will be appreciated by the skilled artisan, in current electronic devices, the channel typically comprises one or more of silicon (Si) or silicon germanium (SiGe). In one or more embodiments, the channel 306 comprises the TMDC film as described herein.

The TMDC films according to one or more embodiments have greater mechanical strength than silicon (Si), and the TMDC films can advantageously be used instead of silicon (Si) or silicon germanium (SiGe), for example, as the channel material (e.g., the channel 306).

In some embodiments, the channel 306 of the N-metal stack 340 and the P-metal stack 350 independently comprises the TMDC film as described herein, and the other of the channel 306 of the N-metal stack 340 and the P-metal stack 350 independently comprises one or more of silicon (Si) or silicon germanium (SiGe). In one or more embodiments, the channel 306 of the N-metal stack 340 comprises the TMDC film as described herein and the channel 306 of the P-metal stack 350 comprises silicon germanium (SiGe).

In some embodiments, the interfacial layer 310 is deposited using a deposition technique, such as, but not limited to, ALD, CVD, PVD, MBE, MOCVD, spin-on, or other insulating layer deposition techniques known to the skilled artisan. In one or more embodiments, the interfacial layer 310 may be formed by etching the substrate 302 and an oxide forming on the top surface 305 of the channel 306. In one or more embodiments, the interfacial layer 310 comprises, consists essentially of, or consists of silicon oxide (SiOx).

The interfacial layer 310 may have any suitable thickness. In some embodiments, the interfacial layer 310 has a thickness in a range of from 1 Angstrom to 10 Angstroms. In one or more embodiments, the thickness of the interfacial layer 310 is in the range of from 6 Angstroms to 8 Angstroms.

In some embodiments, a high-κ dielectric layer 312 is deposited on interfacial layer 310 on the channel 206. In some embodiments, the high-κ dielectric layer 312 is deposited using a deposition technique, such as, but not limited to, ALD, CVD, PVD, MBE, MOCVD, spin-on, or other insulating layer deposition techniques known to the skilled artisan.

The high-κ dielectric layer 312 comprises, consists essentially of, or consists of one or more of hafnium oxide (HfOx), aluminum oxide (AlOx), zirconium oxide (ZrOx), titanium oxide (TiOx), strontium titanium oxide (SrTiOx), epitaxial strontium titanium oxide (SrTiO₃), tantalum oxide (TaOx), any inorganic perovskite having a general formula of ABO₃, where A and B are cations, a lanthanoid oxide, or alloys thereof. As used herein, the term “lanthanoid oxide” refers one or more of lanthanum oxide (LaOx), cerium oxide (CeOx), praseodymium oxide (PrOx), neodymium oxide (NdOx), promethium oxide (PmOx), samarium oxide (SmOx), europium oxide (EuOx), gadolinium oxide (GdOx), terbium oxide (TbOx), dysprosium oxide (DyOx), holmium oxide (HoOx), erbium oxide (ErOx), thulium oxide (TmOx), ytterbium oxide (YbOx), lutetium oxide (LuOx), or alloys thereof.

In one or more embodiments, the high-κ dielectric layer 312 comprises, consists essentially of, or consists of hafnium oxide (HfOx). In one or more embodiments, the high-κ dielectric layer 312 comprises, consists essentially of, or consists of hafnium oxide (HfO₂).

The high-κ dielectric layer 312 may have any suitable thickness. In some embodiments, the high-κ dielectric layer 312 has a thickness in a range of from 1 Angstrom to 50 Angstroms on the interfacial layer 310.

FIG. 3C illustrates the electronic device 300 with the channel 306 shown as a plurality of nanosheets, a trench 308 in between each of the plurality of nanosheets, and a gate trench 355 on each side of the channel 306.

As will be appreciated by the skilled artisan, one or more subsequent operations to complete fabrication of the electronic device 300, such as, for example, filling the trench 308 with a work function material and/or filling gate trench 355 with a gate metal to form a gate contact (also interchangeably referred to as a “metal contact”), falls within the spirit and scope of the present disclosure and can be performed without undue experimentation.

Additional embodiments of the disclosure are directed to the processing system 900 for processing substrates, the formation of the electronic devices, and methods described herein, as shown in FIG. 4.

The processing system 900 includes at least one central transfer station 921, 931 with a plurality of sides. A robot 925, 935 is positioned within the central transfer station a, 931 and is configured to move a robot blade and a wafer, such as, for example, the substrate 202 and/or the substrate 302, to each of the plurality of sides.

The processing system 900 comprises a plurality of processing chambers 902, 904, 906, 908, 910, 912, 914, 916, and 918, also referred to as process stations, connected to the at least one central transfer station 921, 931. The various processing chambers provide separate processing regions isolated from adjacent process stations. The processing chambers can independently be any suitable processing chamber. The particular arrangement of processing chambers and components can be varied depending on the processing system and should not be taken as limiting the scope of the disclosure.

In the embodiment shown in FIG. 4, a factory interface 950 is connected to a front of the processing system 900. The factory interface 950 includes a loading chamber 954 and an unloading chamber 956 on a front 951 of the factory interface 950. While the loading chamber 954 is shown on the left and the unloading chamber 956 is shown on the right, those skilled in the art will understand that this is merely representative of one possible configuration.

The size and shape of the loading chamber 954 and unloading chamber 956 can vary depending on, for example, the substrates being processed in the processing system 900. In the embodiment shown, the loading chamber 954 and unloading chamber 956 are sized to hold a wafer cassette with a plurality of wafers, e.g., a plurality of substrates, positioned within the cassette.

A robot 952 is within the factory interface 950 and can move between the loading chamber 954 and the unloading chamber 956. The robot 952 is capable of transferring a wafer (e.g., a substrate) from a cassette in the loading chamber 954 through the factory interface 950 to load lock chamber 960. The robot 952 is also capable of transferring a wafer from the load lock chamber 962 through the factory interface 950 to a cassette in the unloading chamber 956. As will be understood by those skilled in the art, the factory interface 950 can have more than one robot 952. For example, the factory interface 950 may have a first robot that transfers wafers between the loading chamber 954 and load lock chamber 960, and a second robot that transfers wafers between the load lock chamber 962 and the unloading chamber 956.

The processing system 900 shown has a first section 920 and a second section 930. The first section 920 is connected to the factory interface 950 through load lock chamber 960 and load lock chamber 962. The first section 920 includes at least one central transfer station 921 with at least one robot 925 positioned therein. The robot 925 can also be referred to as a robotic wafer transport mechanism. The at least one central transfer station 921 in the first section 920 is centrally located with respect to the load lock chamber 960 and the load lock chamber 962, process chambers 902, 904, 916, 918, and buffer chambers 922, 924. The robot 925 of some embodiments is a multi-arm robot capable of independently moving more than one wafer at a time. In one or more embodiments, the at least one central transfer station 921 in the first section 920 comprises more than one robotic wafer transfer mechanism. The robot 925 in the at least one central transfer station 921 is configured to move wafers between the chambers around the at least one central transfer station 921. Individual wafers are carried upon a wafer transport blade that is located at a distal end of the first robotic mechanism.

After processing a wafer in the first section 920, the wafer can be passed to the second section 930 through a pass-through chamber. For example, chambers 922, 924 can be uni-directional or bi-directional pass-through chambers. The pass-through chambers 922, 924 can be used, for example, to cryo cool the wafer before processing in the second section 930, or allow wafer cooling or post-processing before moving back to the first section 920.

A system controller 990 is in communication with the first robot 925, second robot 935, first plurality of processing chambers 902, 904, 916, 918 and second plurality of processing chambers 906, 908, 910, 912, 914. The system controller 990 can be any suitable component that can control the processing chambers and robots. For example, the system controller 990 can be a computer including a central processing unit, memory, suitable circuits and storage.

Processes may generally be stored in the memory of the system controller 990 as a software routine that, when executed by the processor, causes the processing system 900 to act in accordance with one or more embodiments of the present disclosure. The software routine may also be stored and/or executed by a second processor (not shown) that is remotely located from the hardware being controlled by the processor. Some or all of the methods of the present disclosure may also be performed in hardware. As such, the process may be implemented in software and executed using a computer system, in hardware as, e.g., an application specific integrated circuit or other type of hardware implementation, or as a combination of software and hardware. The software routine, when executed by the processor, transforms the general purpose computer into a specific purpose computer (controller) that controls the operation such that the processes are performed.

One or more embodiments of the disclosure are directed to a non-transitory computer readable medium including instructions, that, when executed by a controller of a processing system, such as the processing system 900, cause the processing system to perform the operations of the methods described herein.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A method of forming a transition metal dichalcogenide (TMDC) film, the method comprising:
depositing a transition metal oxide film on a substrate by sequentially exposing the substrate to a transition metal precursor and an oxidant without forming a transition metal film intermediate;
converting the transition metal oxide film to the TMDC film; and
performing a rapid thermal anneal (RTA) process.

2. The method of claim 1, further comprising pre-treating the substrate prior to depositing the transition metal oxide film.

3. The method of claim 2, wherein pre-treating the substrate comprises a plasma pre-treatment or ultraviolet (UV) radiation exposure.

4. The method of claim 1, wherein the oxidant comprises one or more of thermal oxygen (O₂), a plasma of oxygen (O₂), thermal ozone (O₃), a plasma of ozone (O₃), an alcohol, or deionized water.

5. The method of claim 1, wherein depositing the transition metal oxide film is performed at a temperature in a range of from 20° C. to 450° C.

6. The method of claim 1, wherein depositing the transition metal oxide film is performed at a pressure in a range of from 1 mTorr to 10 Torr.

7. The method of claim 1, further comprising purging the substrate of the transition metal precursor and the oxidant prior to converting the transition metal oxide film.

8. The method of claim 1, wherein converting the transition metal oxide film to the TMDC film comprises exposing the transition metal oxide film to a chalcogenide precursor at a temperature in a range of from 300° C. to 1000° C. and a pressure in a range of from 1 mTorr to 760 Torr.

9. The method of claim 1, wherein the TMDC film is substantially free of oxygen.

10. The method of claim 1, wherein the TMDC film has a general formula of MX₂, wherein M is a transition metal selected from the group consisting of molybdenum (Mo), tungsten (W), tantalum (Ta), titanium (Ti), niobium (Nb), zirconium (Zr), hafnium (Hf), rhenium (Re), platinum (Pt), palladium (Pd), and nickel (Ni) and X is a chalcogen selected from the group consisting of sulfur (S), selenium (Se), and tellurium (Te).

11. The method of claim 10, wherein the TMDC film comprises molybdenum disulfide (MoS₂).

12. The method of claim 1, wherein the RTA process comprises a first process or a second process.

13. The method of claim 12, wherein the first process comprises exposing the TMDC film to a chalcogenide precursor at a temperature in a range of from 400° C. to 1200° C. and a pressure in a range of from 1 mTorr to 760 Torr for a time period in a range of from 1 second to 60 minutes.

14. The method of claim 12, wherein the second process comprises exposing the TMDC film to an environment comprising one or more of nitrogen (N₂), argon (Ar), or hydrogen (H₂) under vacuum at a temperature in a range of from 400° C. to 1200°C. and a pressure in a range of from 0.01μTorr to 10 Torr for a time period in a range of from 1 second to 60 minutes, followed by exposing the TMDC film to a chalcogenide precursor at a temperature in a range of from 400° C. to 1200° C. and a pressure in a range of from 1 mTorr to 760 Torr for a time period in a range of from 1 second to 60 minutes.

15. A method of forming a transition metal dichalcogenide (TMDC) film, the method comprising:
depositing the TMDC film on a substrate by sequentially exposing the substrate to a transition metal precursor and a chalcogenide precursor at a temperature in a range of from 20° C. to 450° C.;
exposing the TMDC film to the chalcogenide precursor at a temperature in a range of from 300° C. to 1000° C. and a pressure in a range of from 1 mTorr to 760 Torr; and
performing a rapid thermal anneal (RTA) process.

16. A method of forming a transition metal dichalcogenide (TMDC) film, the method comprising:
depositing an amorphous transition metal dichalcogenide (TMDC) film on a substrate by sequentially exposing the substrate to a transition metal precursor and a chalcogenide precursor at a temperature in a range of from 20° C. to 270° C.;
performing a plasma post-treatment process; and
performing a rapid thermal anneal (RTA) process.

17. The method of claim 16, wherein the plasma post-treatment process comprises exposing the amorphous TMDC film to a plasma including one or more of argon (Ar), hydrogen (H₂), nitrogen (N₂), hydrogen sulfide (H₂S), hydrogen selenide (H₂Se), or hydrogen telluride (H₂Te) to form a crystalline TMDC film.

18. The method of claim 17, wherein the RTA process comprises a first process or a second process.

19. The method of claim 18, wherein the first process comprises exposing the crystalline TMDC film to a chalcogenide precursor at a temperature in a range of from 400° C. to 1200° C. and a pressure in a range of from 1 mTorr to 760 Torr for a time period in a range of from 1 second to 60 minutes.

20. The method of claim 18, wherein the second process comprises exposing the crystalline TMDC film to an environment comprising one or more of nitrogen (N₂), argon (Ar), or hydrogen (H₂) under vacuum at a temperature in a range of from 400° C. to 1200° C. and a pressure in a range of from 0.01μTorr to 10 Torr for a time period in a range of from 1 second to 60 minutes, followed by exposing the crystalline TMDC film to a chalcogenide precursor at a temperature in a range of from 400° C. to 1200° C. and a pressure in a range of from 1 Torr to 760 Torr for a time period in a range of from 1 second to 60 minutes.
